(19) United States
(12) Patent Application Publication
(10) Pub. No.: US 2012/0205659 A1
(43) Pub. Date: Aug. 16, 2012

(54) CRYSTALLIZATION APPARATUS, CRYSTALLIZATION METHOD, AND METHOD OF MANUFACTURING ORGANIC LIGHT-EMITTING DISPLAY APPARATUS

(76) Inventor: Kwon-Hyung LEE, Yongin-City (KR)

(21) Appl. No.: 13/326,762

(22) Filed: Dec. 15, 2011

(30) Foreign Application Priority Data
Feb. 11, 2011 (KR) 10-2011-0012457

(51) Int. Cl. H01L 33/16; H01L 29/786; G02B 27/40; H01L 21/20

(52) U.S. Cl. 257/72; 438/487; 250/201.4; 257/40; 257/E33.003; 257/E29.292; 257/E21.09

(57) ABSTRACT

An organic light-emitting display apparatus includes a substrate, a thin film transistor, a reflective layer, and an organic emission device. The thin film transistor includes an active layer patterned on the substrate at a predetermined interval, a gate electrode, and source/drain electrodes. The reflective layer is between the substrate and the active layer. The organic emission device has sequentially stacked therein a pixel electrode electrically connected to the TFT, an intermediate layer including an emission layer, and an opposing electrode.

### CROSS-REFERENCE TO RELATED PATENT APPLICATION

This application claims the benefit of Korean Patent Application No. 10-2011-0012457, filed on Feb. 11, 2011, in the Korean Intellectual Property Office, the disclosure of which is incorporated herein in its entirety by reference.

### BACKGROUND

Active matrix (AM) type organic light-emitting display apparatuses may include a pixel driving circuit in each of pixels. The pixel driving circuit may include a thin film transistor (TFT) formed using, e.g., silicon. Amorphous silicon or polycrystalline silicon may be used as the silicon in the TFT.

### SUMMARY

Embodiments may be realized by providing an organic light-emitting display apparatus including a substrate; a thin film transistor (TFT) that includes an active layer patterned on the substrate at a predetermined interval, a gate electrode, and source/drain electrodes; a reflective layer interposed between the substrate and the active layer; and an organic emission device in which a pixel electrode electrically connected to the TFT, an intermediate layer including an emission layer, and an opposing electrode are sequentially stacked.

The reflective layer may include amorphous silicon.

The active layer may include crystalline silicon formed by crystallizing amorphous silicon by using a laser.

A thickness of the active layer may be formed within an allowable margin range with respect to a focus of a laser in the crystallization.

The organic light-emitting display apparatus may further include a buffer layer interposed between the active layer and the reflective layer.

A sum of thicknesses of the active layer and the buffer layer may be formed within an allowable margin range with respect to a focus of a laser in crystallization.

The sum of the thicknesses of the active layer and the buffer layer may be to be less than 0.3 μm.

Embodiments may also be realized by providing an organic light-emitting display apparatus including a substrate including a region where a plurality of panels spaced apart from one another at a predetermined interval are to be formed; a thin film transistor (TFT) that includes an active layer patterned on the substrate at a predetermined interval, a gate electrode, and source/drain electrodes; and an organic emission device in which a pixel electrode electrically connected to the TFT, an intermediate layer including an emission layer, and an opposing electrode are sequentially stacked, wherein the active layer is formed in a region of each panel, and at least a part of an edge portion of the active layer is formed to extend from the region of each panel by a predetermined length.

The active layer may include crystalline silicon formed by crystallizing amorphous silicon by using a laser.

Embodiments may also be realized by a method of crystallizing a semiconductor material by using a crystallization apparatus including a laser generating apparatus and one or more auto/focus (A/F) sensors, the method including sequentially forming a reflective layer, a buffer layer, and an amorphous silicon layer on a substrate; patterning the amorphous silicon layer to form panels; while the laser generating apparatus and the one or more A/F sensors move together, crystallizing the amorphous silicon layer by using a distance between the crystallization apparatus and the reflective layer or a distance between the crystallization apparatus and the amorphous silicon layer that is measured by the one or more A/F sensors as a focus value, wherein a difference between the distance between the crystallization apparatus and the reflective layer and the distance between the crystallization apparatus and the amorphous silicon layer are formed to be within an allowable margin range of a focus of a laser irradiated from the laser generating apparatus.

Embodiments may also be realized by providing a crystallization apparatus for crystallizing an amorphous silicon layer formed on a substrate, the crystallization apparatus including a laser generating apparatus for irradiating a laser onto the substrate; and one or more A/F sensors that move in one direction together with the laser generating apparatus, wherein when the A/F sensors periodically measure a distance between the crystallization apparatus and the amorphous silicon layer to perform crystallization, if a difference between a previously measured distance value and a currently measured distance value is greater than a predetermined level, the A/F sensors maintain a focus position of a laser irradiated from the laser generating apparatus in a state corresponding to the previously measured distance value.

If the difference between the previously measured distance value and the currently measured distance value is substantially equal to or greater than a thickness of the substrate, the focus position of the laser irradiated from the laser generating apparatus may be maintained in the state corresponding to the previously measured distance value.

### BRIEF DESCRIPTION OF THE DRAWINGS

Features will become apparent to those of ordinary skill in the art by describing in detail exemplary embodiments with reference to the attached drawings in which:

FIG. 1 illustrates a schematic plan view of a crystallization apparatus and a part of an organic light-emitting display apparatus manufactured using the crystallization apparatus, according to an exemplary embodiment;

FIGS. 2A through 2C illustrate sequential cross-sectional side views of a crystallization method, according to an exemplary embodiment;

FIG. 3 illustrates a cross-sectional view of an organic light-emitting display apparatus manufactured using the crystallization method illustrated in FIGS. 2A through 2C;

FIG. 4 illustrates a schematic plan view of a crystallization apparatus and a part of an organic light-emitting display apparatus manufactured using the crystallization apparatus, according to an exemplary embodiment; and

FIG. 5 illustrates a schematic cross-sectional side view of a crystallization apparatus and a part of an organic light-emitting display apparatus manufactured using the crystallization apparatus, according to an exemplary embodiment.

### DETAILED DESCRIPTION

Example embodiments will now be described more fully hereinafter with reference to the accompanying drawings; however, they may be embodied in different forms and should not be construed as limited to the embodiments set forth herein. Rather, these embodiments are provided so that this disclosure will be thorough and complete, and will fully convey the scope of the invention to those skilled in the art.

In the figures, the dimensions of layers and regions may be exaggerated for clarity of illustration. It will also be understood that when a layer or element is referred to as being “on” another layer or substrate, it can be directly on the other layer or element, or intervening layers or elements may also be present. Further, it will be understood that when an element is referred to as being “under” another element, it can be directly under, and one or more intervening elements may also be present. In addition, it will also be understood that when an element is referred to as being “between” two elements, it can be the only element between the two elements, or one or more intervening elements may also be present. Like reference numerals refer to like elements throughout.

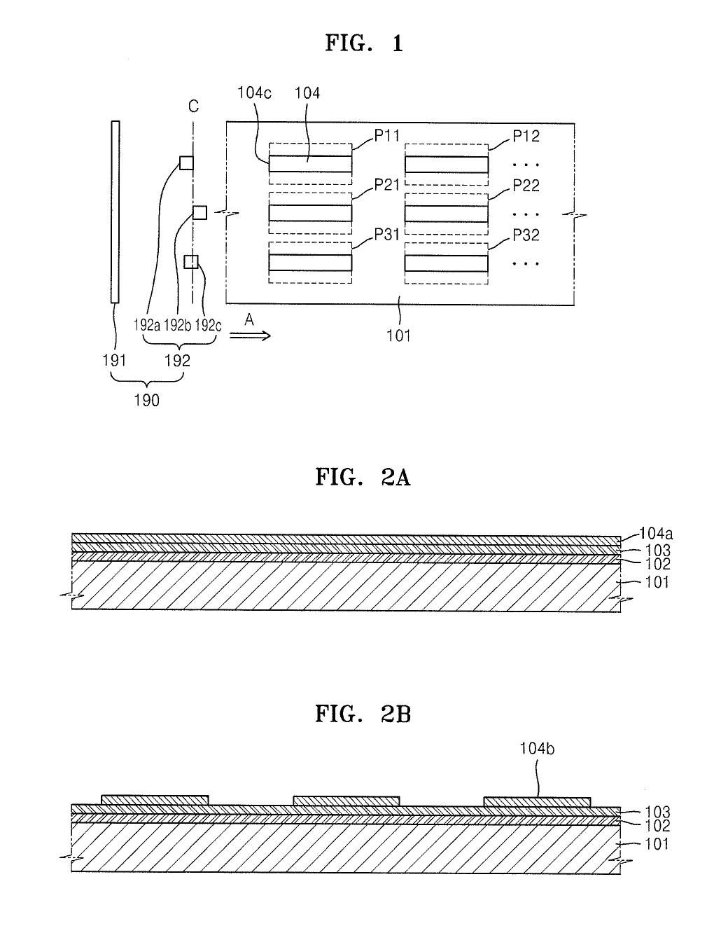

FIG. 1 illustrates a schematic plan view of a crystallization apparatus 190 and a part of an organic light-emitting display apparatus manufactured using the crystallization apparatus 190, according to an exemplary embodiment.

Referring to FIG. 1, the crystallization apparatus 190 may include a laser generating apparatus 191 and one or more auto-focus (A/F) sensors 192.

The organic light-emitting display apparatus may be formed of a plurality of panels, e.g., panels P11, P12, P21, P22, P31, and P32 formed on a substrate 101. Each panel may include an active layer 104 formed of, e.g., polycrystalline silicon. In order for the organic light-emitting display apparatus to become bigger, more panels may be formed on the substrate 101, e.g., on a single mother glass.

As illustrated in FIG. 1, when the panels are disposed in three lines, e.g., three rows, the crystallization apparatus 190 may move in a direction of an arrow A. For example, each line may include a plurality of panels disposed along a first direction, and the crystallization apparatus 190 may move in the first direction. The crystallization apparatus 190 may, e.g., simultaneously crystallize the active layers 104 of the panels of each line belonging to a single column.

As illustrated in FIG. 1, the laser generating apparatus 191 of the crystallization apparatus 190 may be line-beam shaped, e.g., the laser generating apparatus 191 may have a rectangular shape. When the crystallization apparatus 190 moves in the direction of the arrow A, the laser generating apparatus 191, which may have an oblong shape, may simultaneously crystallize the plurality of panels disposed in a single column.

The A/F sensors 192 of the crystallization apparatus 190 disposed in front of the laser generating apparatus 191 may move in the direction of the arrow A together with the laser generating apparatus 191. Each A/F sensor 192 may periodically measure a distance between the crystallization apparatus 190 and the substrate 101 in order to, e.g., adjust a focus of a laser irradiated from the laser generating apparatus 191.

In this regard, FIG. 1 illustrates three A/F sensors 192 disposed in a column, i.e., along a line C. However, embodiments are not limited thereto, e.g., various numbers of A/F sensors 192 may be disposed in various forms so as to correctly measure distances to adjust a focus of a laser irradiated from the crystallization apparatus 190.

Also, FIG. 1 illustrates the panels P11, P12, P21, P22, P31, and P32 disposed in three lines on the substrate 101. However, embodiments are not limited thereto, e.g., the panels may be disposed in various forms.

When the crystallization apparatus 190 is configured to include the plurality of A/F sensors 192 and the line-beam shaped laser generating apparatus 191, crystallization may not be normally performed at an edge portion of each panel, which will be described in detail as follows.

In practice, the laser generating apparatus 191 may not be parallel to the substrate 101, or the plurality of A/F sensors 192 (three A/F sensors 192 in FIG. 1) may not be exactly disposed in a column. That is, as illustrated in FIG. 1, the three A/F sensors 192 may be disposed with slight errors with respect to the line C parallel to the laser generating apparatus 191. In this case, when the A/F sensors 192 move between the panel P11 and the panel P12, which are adjacent to each other (the panel P11 and the panel P12 may be disposed parallel to each other, but in practice, they may not be disposed parallel to each other), some of the plurality of A/F sensors 192 measure distances between the A/F sensors 192 and the active layers 104 and the rest of the A/F sensors 192 measure distances between the A/F sensors 192 and the substrate 101. Accordingly, the laser generating apparatus 191 may be out of focus at a certain section, and thus crystallization may not be normally performed.

For example, as illustrated in FIG. 1, a second A/F sensor 192b may relatively protrude forward a bit in the direction of the arrow A, as compared to first and third A/F sensors 192a and 192c. Thus, when the crystallization apparatus 190 moves forward in the direction of the arrow A, there is a moment when the second A/F sensor 192b is disposed over a region in which the active layers 104 are formed and the first and third A/F sensors 192a and 192c are disposed over a region where the active layers 104 are not formed. Also, there may be a moment when the second A/F sensor 192b is disposed over the region where the active layers 104 are not formed and the first and third A/F sensors 192a and 192c are disposed over the region in which the active layers 104 are formed. At either of these times, crystallization may not be normally performed at edge portions of some of the panels P11, P12, P21, P22, P31, and P32.

According to an exemplary embodiment, a reflective layer 102 may further be disposed between the substrate 101 and the active layers 104 in an organic light-emitting display apparatus 100 such that crystallization may be performed normally even at an edge portion of each panel, which will be described below in detail.

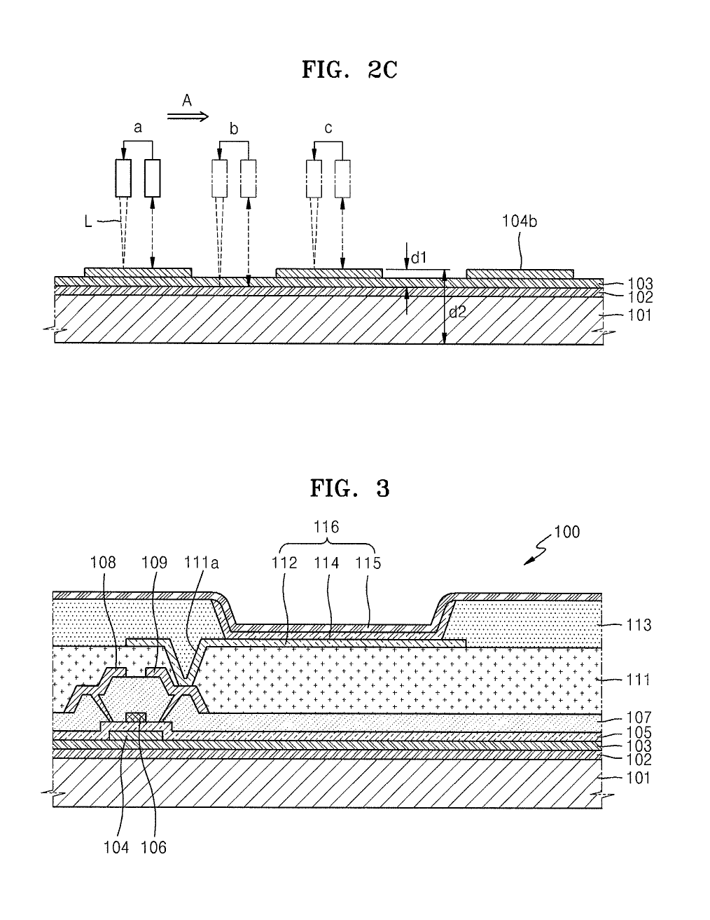

FIGS. 2A through 2C illustrate sequential cross-sectional side views of a crystallization method, according to an exemplary embodiment.

Referring to FIG. 2A, the reflective layer 102, a buffer layer 103, and an amorphous silicon layer 104a are formed on the substrate 101.

The substrate 101 may be formed of a transparent glass mainly including, e.g., SiO₂. However, embodiments are not limited thereto, e.g., the substrate 101 may be formed of a transparent plastic. A plastic substrate may be formed of, e.g., an insulating organic material selected from the group consisting of polyethersulphone (PES), polyacrylate (PAR), polyetherimide (PEI), polyethyelenen napthalate (PEN), polyethyeleneterepthalate (PET), polyphenylene sulfide (PPS), polyallylate, polyimide, polycarbonate (PC), triacetylcellulose (TAC), and cellulose acetate propionate (CAP).

According to another exemplary embodiment, the substrate 101 may be formed of a metal. When the substrate 101 is formed of a metal, the substrate 101 may include one or more metals selected from the group consisting of iron (Fe), chrome (Cr), manganese (Mn), nickel (Ni), titanium (Ti), molybdenum (Mo), stainless steel (SUS), an Invar alloy, an Inconel alloy, and a Kovar alloy, but embodiments not limited thereto. The substrate 101 may have a foil shape.

The reflective layer 102 may be formed on the substrate 101. As illustrated in FIG. 2C, the reflective layer 102 may be formed of a material capable of reflecting light L irradiated from the laser generating apparatus 191. For example the reflective layer 102 may be formed of amorphous silicon. The amorphous silicon may be deposited by using various methods, e.g., a chemical vapor deposition (CVD) method. Alternatively, the reflective layer 102 may be formed of a metal. When the reflective layer 102 is formed of a metal, the reflective layer 102 may include one or more metals selected from the group consisting of silver (Ag), magnesium (Mg), aluminum (Al), platinum (Pt), palladium (Pd), gold (Au), nickel (Ni), neodymium (Nd), iridium (Ir), Chromium (Cr), lithium (Li), and calcium (Ca), but embodiments are not limited thereto.

The buffer layer 103 may be formed on the reflective layer 102, e.g., so as to provide a substantially flat surface on the substrate 101 and/or to prevent impurities from entering the substrate 101. The buffer layer 103 may be formed of, e.g., SiO₂ and/or SiNx.

Then, the amorphous silicon layer 104a is formed on the substrate 101. The amorphous silicon layer 104a may be formed by using various methods, e.g., a CVD method.

As illustrated in FIG. 2B, a plurality of pattern layers 104b may be formed by patterning the amorphous silicon layer 104a according to a predetermined form. The patterning of the amorphous silicon layer 104a may be performed by using, e.g., a photolithography method.

As illustrated in FIG. 2C, light may be irradiated onto the pattern layers 104b formed by patterning the amorphous silicon layer 104a so as to crystallize amorphous silicon included in the pattern layers 104b to polycrystalline silicon, thereby forming the active layers 104, which will be described in detail as follows.

As described above, when the A/F sensors 192 pass over edge portions of the panels, that is, when the A/F sensors 192 move from a region where the pattern layers 104b are formed to a region where the pattern layers 104b are not formed or vice-versa, a focus position may be rapidly changed at the edge portions of the panels, and thus crystallization may not properly performed.

That is, when the reflective layer 102 is not formed between the substrate 101 and the pattern layer 104b, when the A/F sensors 192 are over the region where the pattern layers 104b are not formed, the A/F sensors 192 may measure distances between the A/F sensors 192 and a chuck (not shown) disposed under the substrate 101 by using light reflected by the chuck, and thus the distances measured by the A/F sensors 192 may be d2 of FIG. 2C.

In this case, a laser irradiated from the laser generating apparatus 191 may be focused on a lower portion of the substrate 101. In an organic light-emitting display apparatus, the distance d2 between an upper surface of the pattern layer 104b and a lower surface of the substrate 101 may be, e.g., about 500 μm. Accordingly, when the reflective layer 102 is not formed between the substrate 101 and the pattern layers 104b, a difference between a focus position of a laser in the region where the pattern layers 104b are formed and a focus position of a laser in the region where the pattern layers 104b are not formed is about 500 μm, and the difference may significantly affect crystallization of the pattern layers 104b. That is, at the same time as when the laser generating apparatus 191 passes over edge portions of the pattern layers 104b, a focus position of a laser should be changed from the lower surface of the substrate 101 to the upper surface of the pattern layer 104b. However, this may not occur, e.g., may not be realistically possible, and thus defective crystallization may occur at edge portions of the pattern layers 104b.

According to an exemplary embodiment, when the reflective layer 102 is formed between the substrate 101 and the pattern layers 104b, when the A/F sensors 192 are over the region where the pattern layers 104b are not formed, the A/F sensors 192 may measure distances between the A/F sensors 192 and the reflective layer 102 by using light reflected by the reflective layer 102. Accordingly, the distances measured by the A/F sensor 192 may be d1 of FIG. 2C. Since the buffer layer 103 and the pattern layers 104b formed on the reflective layer 102 may be formed to be extremely thin, e.g., by deposition, the distance d1 between the upper surface of the pattern layer 104b and an upper surface of the reflective layer 102 may be less than, e.g., 0.3 μm. This difference between focus positions may be within an allowable margin range, and thus the difference may hardly affect a crystallization quality.

In conclusion, when the reflective layer 102 is not formed between the substrate 101 and the pattern layers 104b, a difference between a focus position of a laser in the region where the pattern layers 104b are formed and a focus position of a laser in the region where the pattern layers 104b are not formed may be more than 500 μm. This difference may affect a crystallization quality, and thus there is a possibility that defective crystallization may occur at, e.g., an edge portion of each panel, that is, where a focus position changes. Meanwhile, when the reflective layer 102 is formed between the substrate 101 and the pattern layers 104b, the difference between a focus position of a laser in the region where the pattern layers 104b are formed and a focus position of a laser in the region where the pattern layers 104b are not formed may be about less than 0.3 μm, and thus crystallization may be normally performed at an edge portion of each panel.

Table 1 shows results of an experiment. The results show that when a focus position changes within an allowable margin range, crystallization quality may be maintained almost uniformly. An exemplary allowable margin range of a focus of a laser in crystallization, i.e., for crystallization, is about ±29 μm. As shown in Table 1, when a focus position change is within ±20 μm from a reference point, various factors affecting crystallization, e.g., Vₜₕ sat, Mobility, and s factor, at different positions, that is, +20 μm, +10 μm, 0, −10 μm, and −20 μm, are mostly unchanged and distributions thereof are extremely narrow.

TABLE 1

| | Vₜₕ sat(V) | | | | | | | | | | | |
|---|---|---|---|---|---|---|---|---|---|---|---|---|
| | | Std | Mobility | | s factor | | | | | | | |
| | AVG | (distri- | (cm²/Vs) | | (V/dec) | | Ion(uA/μm) | | Ioff(pA) | | Dr range(V) | |
| Focus | (average) | bution) | AVG | Std | AVG | Std | AVG | Std | AVG | Std | AVG | Std |
| Focus +20 | −1.28 | 0.105 | 75.736 | 3.5504 | 0.29 | 0.017 | −5.06 | 0.217 | 3.07 | 1.303 | −1.51 | 0.04 |
| Focus +10 | −1.32 | 0.076 | 69.792 | 4.2504 | 0.29 | 0.014 | −4.73 | 0.321 | 2.41 | 0.921 | −1.56 | 0.06 |
| Focus 0.0 | −1.31 | 0.07 | 75.00 | 4.08 | 0.27 | 0.01 | −5.12 | 0.27 | 0.74 | 0.32 | −1.47 | 0.04 |
| Focus −10 | −1.33 | 0.057 | 70.032 | 3.1488 | 0.27 | 0.008 | −4.73 | 0.163 | 2.22 | 0.898 | −1.50 | 0.03 |
| Focus −20 | −1.29 | 0.043 | 71.464 | 6.62 | 0.29 | 0.006 | −4.80 | 0.386 | 2.06 | 0.823 | −1.55 | 0.05 |

Thus, defective crystallization due to defocusing of a laser between panels may be minimized and/or prevented from occurring at an edge portion of each panel.

The above-described crystallization method may be applied to various fields. In detail, the above-described crystallization method may be used to manufacture an organic light-emitting display apparatus, and hereinafter, an organic light-emitting display apparatus manufactured by using the above-described crystallization method will be described.

FIG. 3 illustrates a cross-sectional view illustrating an organic light-emitting display apparatus manufactured using the crystallization method illustrated in FIGS. 2A through 2C.

With respect to one of the active layers 104, after the active layer 104 is formed by using the crystallization method illustrated in FIGS. 2A through 2C, a gate insulating layer 105 and a gate electrode 106 may be formed on the active layer 104. The gate insulating layer 105 may be formed of, e.g., various insulating materials so as to insulate the active layer 104 from the gate electrode 106. The gate electrode 106 may be formed of e.g., various metals and/or a metal alloy.

A source region and a drain region may be formed in the active layer 104 by, e.g., doping impurities on the active layer 104 by using the gate electrode 106 as a mask. An insulating interlayer 107 may be formed to cover the gate electrode 106. A source electrode 108 and a drain electrode 109 may be formed on the insulating interlayer 107 so as to be respectively connected to the source region and the drain region of the active layer 104, thereby completing a TFT.

In an exemplary embodiment, the TFT has a top gate structure, e.g., as illustrated in FIG. 3. However, embodiments are not limited thereto, e.g., various TFTs using a polycrystalline silicon layer as an active layer may be used.

A planarization layer 111 including a via-hole 111a may be formed on the source electrode 108 and the drain electrode 109. The planarization layer 111 may be formed of, e.g., an insulating material including an organic material and/or an inorganic material.

An organic emission device 116 may be formed to be electrically connected to the drain electrode 109. The organic emission device 116 may include a first electrode 112, an intermediate layer 114 including an organic emission layer, and a second electrode 115.

The first electrode 112 may be formed on the planarization layer 111 and may be formed as a transparent electrode or a reflective electrode. When the first electrode 112 is formed as a transparent electrode, the first electrode 112 may be formed of, e.g., indium tin oxide (ITO), indium zinc oxide (IZO), zinc oxide (ZnO), or In₂O₃. When the first electrode 112 is formed as a reflective electrode, the first electrode 112 may be formed by, e.g., forming a reflective layer of one or more selected from the group consisting of Ag, Mg, Al, Pt, Pd, Au, Ni, Nd, Ir, and Cr and then forming a layer of ITO, IZO, ZnO, or In₂O₃ on the reflective layer. The organic emission device 116 may be formed to be electrically connected to the drain electrode 109. However, embodiments are not limited thereto, e.g., the organic emission device 116 may contact any one of the source electrode 108 and the drain electrode 109 via the via-hole 111a and the first electrode 112.

A pixel-defining layer 113 may be formed on the first electrode 112. The pixel-defining layer 113 may be formed of an organic material or an inorganic material so as to expose a predetermined region of the first electrode 112.

The intermediate layer 114 may be formed to contact the first electrode 112. The intermediate layer 114 may emit light by, e.g., electrically driving the first electrode 112 and the second electrode 115. The intermediate layer 114 may be formed of an organic material. When the organic emission layer of the intermediate layer 114 is formed of a relatively low molecular organic material, a hole transport layer (HTL) and a hole injection layer (HIL) may be stacked on a side of the organic emission layer facing the first electrode 112, and an electron transport layer (ETL) and an electron injection layer (EIL) may be stacked on a side of the organic emission layer facing the second electrode 115. Also, various other layers may be stacked when required. Examples of an organic material that may be used in the intermediate layer 114 are copper phthalocyanine (CuPc), N,N-Di(naphthalene-1-yl)-N,N′-diphenyl-benzidine (NPB), and tris-8-hydroxyquinoline aluminum (Alq3).

When the organic emission layer of the intermediate layer 114 is formed of a relatively high molecular organic material, only an HTL may be formed on the side of the organic emission layer facing the first electrode 112. The HTL may be formed of poly-2,4-ethylene-dihydroxy thiophene (PEDOT) or polyaniline (PANT) on the first electrode 112 by inkjet printing or spin coating. The organic emission layer may be formed of PPV, Soluble PPV's, Cyano-PPV, or polyfluorene, and the organic emission layer may form a color pattern by using a general method such as an inkjet printing method, a spin coating method, or a thermal transfer method.

The second electrode 115 may be formed on the intermediate layer 114. The second electrode 115 may be formed by depositing a metal having a relatively low work function, e.g., any one selected from the group consisting of Ag, Mg, Al, Pt, Pd, Au, Ni, Nd, Ir, Cr, Li, and Ca or a combination thereof, and then by depositing a transparent conductive material, e.g., ITO, IZO, ZnO, or In₂O₃, thereon.

A sealing member (not shown) may be disposed on the second electrode 115 so as to, e.g., protect the intermediate layer 114 and other layers against external moisture and oxygen. The sealing member may be formed of a transparent material, e.g., glass or plastic. The sealing member may have a structure in which a plurality of organic materials and a plurality of inorganic materials are repeatedly stacked.

Thus, defective crystallization due to defocusing of a laser between panels may be minimized and/or prevented from occurring at an edge portion of each panel.

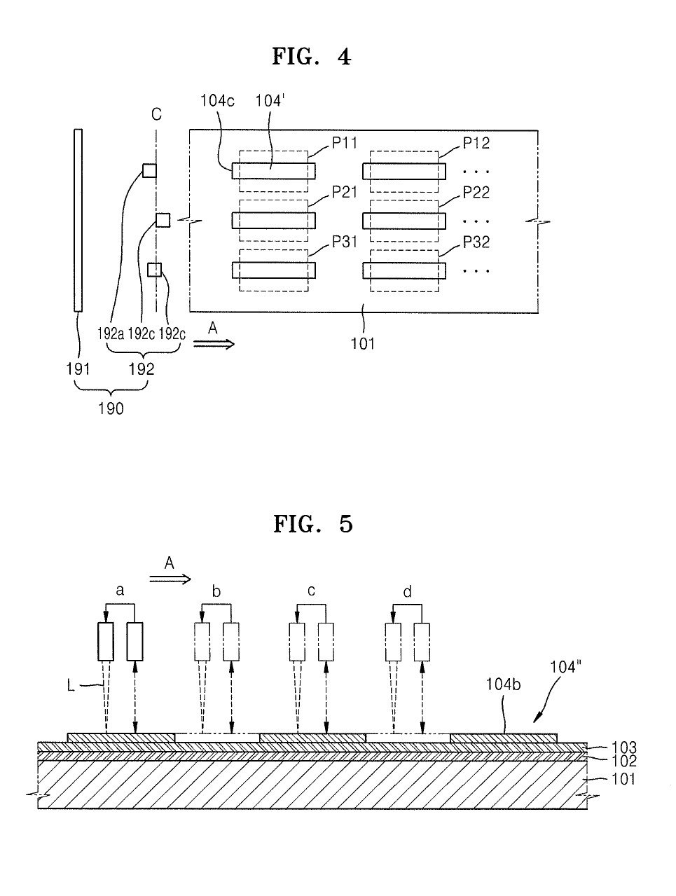

FIG. 4 illustrates a schematic plan view of a crystallization apparatus 190 and a part of an organic light-emitting display apparatus manufactured using the crystallization apparatus 190, according to an exemplary embodiment.

Referring to FIG. 4, the crystallization apparatus 190 may include a laser generating apparatus 191 and one or more A/F sensors 192.

The organic light-emitting display apparatus may be formed of a plurality of panels, e.g., panels P11, P12, P21, P22, P31, and P32 formed on a substrate 101. Each panel may include an active layer 104′ formed of, e.g., polycrystalline silicon. In order for the organic light-emitting display apparatus to become bigger, more panels may be formed on the substrate 101, e.g., on a single mother glass.

The crystallization apparatus 190 and the organic light-emitting display apparatus manufactured by using the crystallization apparatus 190 according to an exemplary embodiment illustrated in FIG. 4 have structures that are the substantially similar and/or the same to those of the crystallization apparatus 190 and the organic light-emitting display apparatus according to the embodiments described with reference to FIGS. 1 through 3. Except, that the crystallization apparatus 190 and the organic light-emitting display apparatus according to the exemplary embodiment described in FIG. 4, does not include a reflective layer and the active layers 104′ are formed to extend from regions of the panels by a predetermined length, which will be described below in detail.

As described above, the plurality of A/F sensors 192 (three A/F sensors 192 in FIG. 4) may not be exactly disposed in a column, e.g., along the same position with respect to line C. That is, as illustrated in FIG. 4, the three A/F sensors 192 may be disposed with slight errors with respect to the line C, which may be parallel to the laser generating apparatus 191. When the A/F sensors 192 move between the panel P11 and the panel P12, which are adjacent to each other, some of the plurality of A/F sensors 192 measure distances between the A/F sensors 192 and the active layers 104′ and the rest of the A/F sensors 192 measure distances between the A/F sensors 192 and the substrate 101. Accordingly, the laser generating apparatus 191 is out of focus at a certain section, and thus crystallization may not be normally performed.

According to an exemplary embodiment, in the crystallization apparatus 190 and the organic light-emitting display apparatus manufactured by using the crystallization apparatus 190, end portions 104c of each active layer 104′ may be formed to extend with respect to a moving direction of the crystallization apparatus 190 by a predetermined length. The end portions 104c may extend outside an area of the corresponding panels. For example, as illustrated in FIG. 4, the active layer 104′ in panel P11 may include two end portions 104c that extend outside an area of the panel P11 at opposing sides of the panel P11. The two end portions 104c in the panel P11 may extend outside the area of the panel P11 by a predetermined length.

For example, as illustrated in FIG. 4, since a second A/F sensor 192b may protrude forward a bit in a direction of an arrow A compared to first and third A/F sensors 192a and 192c, when the crystallization apparatus 190 moves forward in the direction of the arrow A, the second A/F sensor 192b may first reach a position corresponding to the end portion 104c of the active layer 104′ of the panel P21. At this time, the second A/F sensor 192b may measure a distance between the crystallization apparatus 190 and an upper surface of the active layer 104′. Thereafter, the first A/F sensor 192a and the third A/F sensor 192c may reach positions corresponding to the end portions 104c of the active layers 104′ of the panel P11 and P31, respectively. Thus, a laser irradiated from the laser generating apparatus 191 may be focused on the upper surfaces of the active layers 104′, and afterwards, when the laser generating apparatus 191 passes over the upper surfaces of the active layers 104′, crystallization may be performed.

That is, both end portions 104c of the active layers 104′ may be formed to extend from regions of the panels by a predetermined length, so that a plurality of A/F sensors 192 may recognize a change in whether the active layers 104′ exist to have time to change a focus position of a laser irradiated from the laser generating apparatus 191, thereby minimizing and/or preventing defective crystallization from occurring at an edge portion of each panel without including an additional reflective layer.

FIG. 5 illustrates a schematic cross-sectional side view of a crystallization apparatus 190 (not shown), and a part of an organic light-emitting display apparatus manufactured using the crystallization apparatus 190, according to an exemplary embodiment.

Referring to FIG. 5, the crystallization apparatus 190 of the exemplary embodiment may include a laser generating apparatus 191 and one or more A/F sensors 192.

The organic light-emitting display apparatus may be formed of a plurality of panels formed on a substrate 101. Each panel may include an active layer 104″ formed of, e.g., polycrystalline silicon. In order for the organic light-emitting display apparatus to become bigger, more panels may be formed on the substrate 101, e.g., on a single mother glass.

The crystallization apparatus 190 and the organic light-emitting display apparatus manufactured by using the crystallization apparatus 190 according to the exemplary embodiment have structures that are the substantially similar and/or the same as those of the crystallization apparatus 190 and the organic light-emitting display apparatus according to the embodiments described with reference to FIGS. 1 through 3. Except, that in the crystallization apparatus 190 and the organic light-emitting display apparatus according to the exemplary embodiment described in FIG. 5, when any of the distance values measured by the A/F sensors 192 change by a predetermined level, a previously measured distance value is used as a focus position of a laser irradiated from the laser generating apparatus 191, which will be described below in detail.

As described above, the A/F sensors 192 may periodically measure distances between the crystallization apparatus 190 and an organic light-emitting display apparatus. At this time, measured values of the A/F sensors 192 may rapidly change when the A/F sensors 192 move from a region where the active layers 104″ are not formed to a region where the active layers 104″ are formed or when the A/F sensors 192 move from the region where the active layers 104″ are formed to the region where the active layers 104″ are not formed.

Accordingly, while the A/F sensors 192 may periodically measure the distances between the crystallization apparatus 190 and the organic light-emitting display apparatus 100″. When the measured distance values are greater than a predetermined value, that is, when a difference between the measured distance values is approximately similar to a thickness of the substrate 101, it is determined that the A/F sensors 192 have moved from the region where the active layers 104″ are formed to the region where the active layers 104″ are not formed. Thus, a previously measured distance value is used as a focus position of a laser irradiated from the laser generating apparatus 191, because since an object to be crystallized does not exist in the region where the active layers 104″ are not formed, it does not matter where a laser irradiated from the laser generating apparatus 191 is focused on. However, since a laser irradiated from the laser generating apparatus 191 is to be focused, e.g., exactly focused, in the region where the active layers 104″ are formed, a focus position of a laser in the region where the active layers 104″ are not formed is constantly maintained to be a focus position of a laser in the region where the active layers 104″ are formed.

Thus, even while the A/F sensors 192 pass over the region where the active layers 104″ are not formed, the A/F sensors 192 may periodically measure the distances between the crystallization apparatus 190 and the organic light-emitting display apparatus 100″. When it is determined that any of the measured distance values is within a range of the region where the active layers 104″ are formed, the A/F sensors 192 may adjust a focus position again in real time.

Thus, defective crystallization may be minimized and/or prevented from occurring at an edge portion of each panel only by controlling software without including an additional reflective layer.

According to an exemplary embodiment, defective crystallization, e.g., due to defocusing of a laser between panels may be minimized and/or prevented from occurring at an edge portion of each panel.

By way of summation and review, an amorphous silicon TFT (a-Si TFT) may be used in a pixel driving circuit; however, since a semiconductor active layer thereof constituting a source, a drain, and a channel may be formed of amorphous silicon, the amorphous silicon TFT may have low electron mobility. Thus, a polycrystalline silicon TFT, instead of an amorphous silicon TFT, is proposed. A polycrystalline silicon TFT may have high electron mobility and superior light irradiation stability when compared to an amorphous silicon TFT. Thus, polycrystalline silicon may be well adapted for being used as an active layer of a driving and/or switching TFT of an active matrix organic light emitting display apparatus.

A polycrystalline silicon TFT may be manufactured using various methods. Examples of the various methods are a method in which polycrystalline silicon is directly deposited, and a method in which amorphous silicon is deposited and then the deposited amorphous silicon is crystallized. The method of depositing polycrystalline silicon includes one of, e.g., a chemical vapor deposition (CVD) method, a photo CVD method, a hydrogen radical (HR) CVD method, an electron cyclotron resonance (ECR) CVD method, a plasma enhanced (PE) CVD method, and a low pressure (LP) CVD method.

The method in which amorphous silicon is deposited and then the deposited amorphous silicon is crystallized includes one of, e.g., a solid phase crystallization (SPC) method, an excimer laser crystallization (ELC) method, a metal induced crystallization (MIC) method, a metal induced lateral crystallization (MILC) method, and a sequential lateral solidification (SLS) method.

Embodiments, e.g., the exemplary embodiments discussed above, relate to a crystallization apparatus, a crystallization method, and a method of manufacturing an organic light-emitting display apparatus. The crystallization apparatus may minimize and/or prevent defective crystallization from occurring at an edge portion of each of panels due to, e.g., defocusing of a laser between the panels in crystallizing amorphous silicon formed on a substrate to poly-crystalline silicon.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An organic light-emitting display apparatus, comprising:
a substrate;
a thin film transistor (TFT) that includes an active layer patterned on the substrate at a predetermined interval, a gate electrode, and source/drain electrodes;
a reflective layer between the substrate and the active layer; and
an organic emission device, the organic emission device having sequentially stacked therein a pixel electrode electrically connected to the TFT, an intermediate layer including an emission layer, and an opposing electrode.

2. The organic light-emitting display apparatus of claim 1, wherein the reflective layer includes amorphous silicon.

3. The organic light-emitting display apparatus of claim 1, wherein the active layer includes laser-crystallized crystalline silicon, the laser-crystallized crystalline silicon being formed by crystallizing amorphous silicon using a laser for crystallization.

4. The organic light-emitting display apparatus of claim 3, a thickness of the active layer is within an allowable margin range with respect to a focus of the laser for crystallization.

5. The organic light-emitting display apparatus of claim 1, further comprising a buffer layer between the active layer and the reflective layer.

6. The organic light-emitting display apparatus of claim 5, wherein a sum of thicknesses of the active layer and the buffer layer is within an allowable margin range with respect to a focus of a laser for crystallization.

7. The organic light-emitting display apparatus of claim 6, wherein the sum of the thicknesses of the active layer and the buffer layer is less than about 0.3 μm.

8. An organic light-emitting display apparatus, comprising:
a substrate including a region from which a plurality of panels are formed in a spaced apart relationship from one another at a first predetermined interval;
a thin film transistor (TFT), the TFT including an active layer patterned on the substrate at a second predetermined interval, a gate electrode, and source/drain electrodes; and
an organic emission device, the organic emission device having sequentially stacked therein a pixel electrode electrically connected to the TFT, an intermediate layer including an emission layer, and an opposing electrode,
the active layer being in an area of one panel of the plurality of panels, and at least a part of an edge portion of the active layer extending outside the area of the one panel by a predetermined length.

9. The organic light-emitting display apparatus of claim 8, wherein the active layer includes laser-crystallized crystalline silicon, the laser-crystallized silicon being formed by crystallizing amorphous silicon using a laser for crystallization.

10. A method of crystallizing a semiconductor material by using a crystallization apparatus including a laser generating apparatus and one or more auto/focus (A/F) sensors, the method comprising:
sequentially forming a reflective layer, a buffer layer, and an amorphous silicon layer on a substrate;
patterning the amorphous silicon layer to form panels;
while the laser generating apparatus and the one or more A/F sensors move together, crystallizing the amorphous silicon layer by using a distance between the crystallization apparatus and the reflective layer or a distance between the crystallization apparatus and the amorphous silicon layer that is measured by the one or more A/F sensors as a focus value,
wherein a difference between the distance between the crystallization apparatus and the reflective layer or a difference between the distance between the crystallization apparatus and the amorphous silicon layer is within an allowable margin range of a focus of a laser irradiated from the laser generating apparatus.

11. A crystallization apparatus for crystallizing an amorphous silicon layer formed on a substrate, the crystallization apparatus comprising:
a laser generating apparatus for irradiating a laser onto the substrate; and
one or more A/F sensors that move in one direction together with the laser generating apparatus,
wherein, when the one or more A/F sensors periodically measure a distance between the crystallization apparatus and the amorphous silicon layer to perform crystallization, if a difference between a previously measured distance value and a currently measured distance value of one A/F sensor of the one or more A/F sensors is greater than a predetermined level, the one A/F sensor maintains a focus position of a laser irradiated from the laser generating apparatus in a state corresponding to the previously measured distance value.

12. The crystallization apparatus of claim 11, wherein, if the difference between the previously measured distance value and the currently measured distance value of the one A/F sensor is substantially equal to or greater than a thickness of the substrate, the focus position of the laser irradiated from the laser generating apparatus is maintained in the state corresponding to the previously measured distance value.
